(19) United States
(12) Patent Application Publication
(10) Pub. No.: US 2025/0095760 A1
(43) Pub. Date: Mar. 20, 2025

(54) SEMICONDUCTOR MEMORY DEVICE

(71) Applicant: Kioxia Corporation, Tokyo (JP)

(72) Inventor: Takatoshi MINAMOTO, Kamakura Kanagawa (JP)

(73) Assignee: Kioxia Corporation, Tokyo (JP)

(21) Appl. No.: 18/823,749

(22) Filed: Sep. 4, 2024

(30) Foreign Application Priority Data
Sep. 19, 2023 (JP) 2023-151581

(51) Int. Cl. G11C 16/34; G11C 16/04; G11C 16/10

(52) U.S. Cl. CPC G11C 16/3459; G11C 16/0483; G11C 16/102

(57) ABSTRACT

According to embodiments, a semiconductor memory device includes a memory string including a first select transistor, a first memory cell, and a second memory cell, a bit line, a first word line, a second word line, and a control circuit configured to execute a write operation including a program operation and a program verify operation. The control circuit is configured to raise a voltage of the second word line to a first voltage based on a first condition, in a case of executing the program verify operation of the first memory cell, and to raise a voltage of the first word line to the first voltage based on a second condition different from the first condition, in a case of executing the program verify operation of the second memory cell.

### CROSS-REFERENCE TO RELATED APPLICATION

This application is based upon and claims the benefit of priority from Japanese Patent Application No. 2023-151581, filed Sep. 19, 2023, the entire contents of which are incorporated herein by reference.

### FIELD

Embodiments described herein relate generally to a semiconductor memory device.

### BACKGROUND

NAND flash memories are known as a semiconductor memory device.

### BRIEF DESCRIPTION OF THE DRAWING(S)

FIG. 1 is a block diagram showing an overall configuration of a semiconductor memory device according to a first embodiment.

FIG. 2 is a circuit diagram of a memory cell array included in the semiconductor memory device according to the first embodiment.

FIG. 3 is a cross-sectional diagram of the memory cell array included in the semiconductor memory device according to the first embodiment.

FIG. 4 is a diagram showing threshold voltage distributions and data allocation in a case where memory cell transistors included in the semiconductor memory device according to the first embodiment are triple level cells (TLC) which can store data of 3 bits (8 values).

FIG. 5 is a diagram showing an order of writing data in a NAND string included in the semiconductor memory device according to the first embodiment.

FIG. 6 is a diagram showing write states of memory cell transistors when a word line group WG0 is selected in the semiconductor memory device according to the first embodiment.

FIG. 7 is a diagram showing write states of memory cell transistors when a word line group WG1 is selected in the semiconductor memory device according to the first embodiment.

FIG. 8 is a diagram showing write states of memory cell transistors when a word line group WG2 is selected in the semiconductor memory device according to the first embodiment.

FIG. 9 is a timing chart showing a voltage of each interconnect in a program operation and a program verify operation in the semiconductor memory device according to the first embodiment.

FIG. 10 is a timing chart showing a voltage and a current of non-selected word lines in the program verify operation and a diagram showing a comparison example of states of NAND strings.

FIG. 11 is a timing chart showing a voltage and a current of non-selected word lines in the program verify operation and a diagram showing a comparison example of states of NAND strings.

FIG. 12 is a diagram showing a voltage and a current of non-selected word lines in a period between time t5 and time t6 described with reference to FIG. 9, in a case where the word line group WG0 is selected in the semiconductor memory device according to the first embodiment.

FIG. 13 is a diagram showing a voltage and a current of non-selected word lines in a period between time t5 and time t6 described with reference to FIG. 9, in a case where the word line group WG1 is selected in the semiconductor memory device according to the first embodiment.

FIG. 14 is a diagram showing a voltage and a current of non-selected word lines in a period between time t5 and time t6 described with reference to FIG. 9, in a case where the word line group WG2 is selected in the semiconductor memory device according to the first embodiment.

FIG. 15 is a diagram showing a voltage and a current of non-selected word lines in a period between time t5 and time t6 described with reference to FIG. 9, in a case where the word line group WG0 is selected in a semiconductor memory device according to a second embodiment.

FIG. 16 is a diagram showing a voltage and a current of non-selected word lines in a period between time t5 and time t6 described with reference to FIG. 9, in a case where the word line group WG1 is selected in the semiconductor memory device according to the second embodiment.

FIG. 17 is a diagram showing a voltage and a current of non-selected word lines in a period between time t5 and time t6 described with reference to FIG. 9, in a case where the word line group WG2 is selected in the semiconductor memory device according to the second embodiment.

### DETAILED DESCRIPTION

In general, according to one embodiment, a semiconductor memory device includes a memory string including a first select transistor, a first memory cell, and a second memory cell which are coupled in series, a bit line coupled to the first select transistor, a first word line coupled to the first memory cell, a second word line coupled to the second memory cell, and a control circuit configured to execute a write operation including a program operation and a program verify operation. The control circuit is configured to raise a voltage of the second word line to a first voltage based on a first condition, in a case of executing the program verify operation of the first memory cell, and to raise a voltage of the first word line to the first voltage based on a second condition different from the first condition, in a case of executing the program verify operation of the second memory cell.

Hereinafter, embodiments will be described with reference to the drawings. In the description below, structural elements having the same functions and configurations will be denoted by a common reference symbol. To distinguish a plurality of structural elements having a common reference symbol from each other, an appended symbol is added after the common reference symbol. Note that, in a case where the plurality of structural elements do not need to be particularly distinguished, only the common reference numerals are attached to the plurality of components, and no appended symbols are attached thereto. Herein, appended symbols are not limited to subscripts or superscripts, and they may be lower-case alphabetical letters added to reference symbols, and indices that indicate an array.

### 1. First Embodiment

A semiconductor memory device 1 according to the first embodiment will be described. The semiconductor memory device 1 is, for example, a NAND flash memory, which is capable of storing data in a non-volatile manner. The semiconductor memory device 1 is not limited to a NAND flash memory. The semiconductor memory device 1 may be any other type of non-volatile memory.

### 1. 1 Configuration

### 1. 1. 1 Overall Configuration of Semiconductor Memory Device

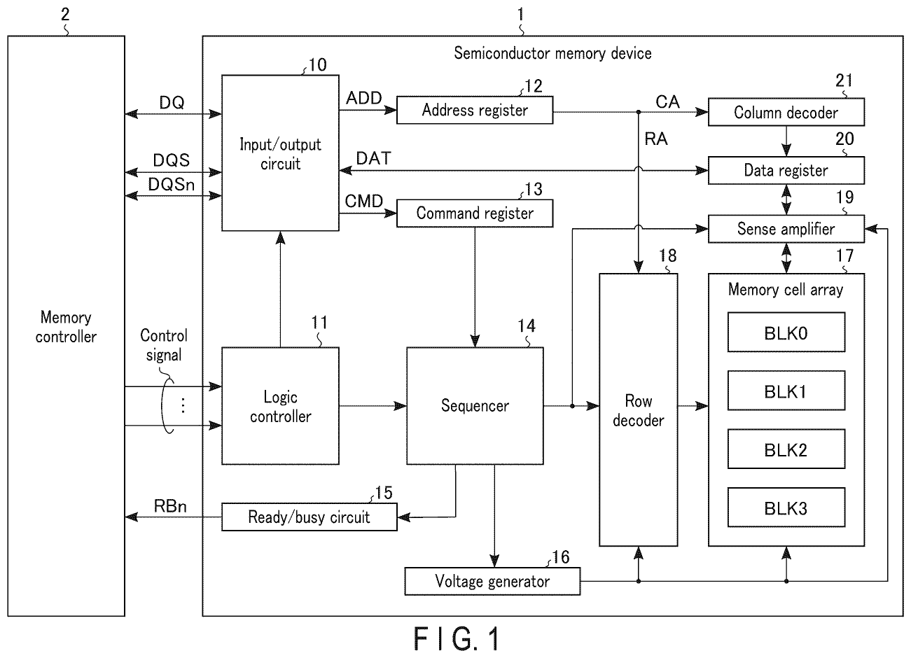

First, an example of an overall configuration of the semiconductor memory device 1 will be described with reference to FIG. 1. FIG. 1 is a block diagram showing an overall configuration of the semiconductor memory device 1. In FIG. 1, some of the couplings between the structural elements are indicated by arrows; however, the couplings between the structural elements are not limited to those shown in FIG. 1.

As illustrated in FIG. 1, the semiconductor memory device 1 is configured to be controllable by an external memory controller 2. For example, the semiconductor memory device 1 transmits and receives a signal DQ and timing signals DQS and DQSn to and from the memory controller 2. The signal DQ is, for example, data DAT, an address ADD, or a command CMD. The timing signals DQS and DQSn are timing signals for use in inputting and outputting the data DAT. The timing signal DQSn is an inversion signal of the timing signal DQS.

The semiconductor memory device 1 also receives various control signals from the memory controller 2. Then, the semiconductor memory device 1 transmits a ready/busy signal RBn to the memory controller 2. The ready/busy signal RBn is a signal indicative of whether the semiconductor memory device 1 is in a state of being unable to receive a command CMD (busy state) or a state of being able to receive a command CMD (ready state) from the memory controller 2.

The semiconductor memory device 1 includes an input/output circuit 10, a logic controller 11, an address register 12, a command register 13, a sequencer 14, a ready/busy circuit 15, a voltage generator 16, a memory cell array 17, a row decoder 18, a sense amplifier 19, a data register 20, and a column decoder 21.

The input/output circuit 10 is a circuit which performs input and output of the signal DQ. The input/output circuit 10 is coupled to the memory controller 2. The input/output circuit 10 is also coupled to the logic controller 11, the address register 12, the command register 13, and the data register 20.

In a case where the input signal DQ is an address ADD, the input/output circuit 10 transmits the address ADD to the address register 12. In a case where the input signal DQ is a command CMD, the input/output circuit 10 transmits the command CMD to the command register 13.

In a case where the input signal DQ is data DAT, the input/output circuit 10 receives the input signal DQ based on timing signals DQS and DQSn. The input/output circuit 10 transmits the data DAT to the data register 20. The input/output circuit 10 also outputs the data DAT to the memory controller 2 along with the timing signals DQS and DQSn.

The logic controller 11 is a circuit that performs logic control based on the control signals. The logic controller 11 is coupled to the memory controller 2. The logic controller 11 is also coupled to the input/output circuit 10 and the sequencer 14. The logic controller 11 receives a plurality of control signals from the memory controller 2. The logic controller 11 controls the input/output circuit 10 and the sequencer 14 based on the received control signals.

The address register 12 is a register that temporarily stores the address ADD. The address register 12 is coupled to the input/output circuit 10, the row decoder 18, and the column decoder 21. The address ADD includes a row address RA and a column address CA. The row address RA is an address to select interconnects (word lines and a select gate lines) arranged in a row direction in the memory cell array 17. The column address CA is an address to select interconnects (bit lines) arranged in a column direction in the memory cell array 17. For example, the row address RA includes a block address and a word line address. The block address is an address that designates any one of a plurality of blocks BLK included in the memory cell array 17. The word line address is an address that designates any one of a plurality of word lines coupled to a block BLK.

The address register 12 transfers the row address RA to the row decoder 18. The address register 12 also transfers the column address CA to the column decoder 21.

The command register 13 is a register that temporarily stores the command CMD. The command register 13 is coupled to the input/output circuit 10 and the sequencer 14. The command register 13 transfers the command CMD to the sequencer 14.

The sequencer 14 is a control circuit that performs control of the semiconductor memory device 1. The sequencer 14 controls the entire operation of the semiconductor memory device 1. For example, the sequencer 14 controls the ready/busy circuit 15, the voltage generator 16, the row decoder 18, the sense amplifier 19, the data register 20, and the column register 21. More specifically, the sequencer 14 executes, for example, a write operation, a read operation, an erase operation, etc. based on the command CMD.

The ready/busy circuit 15 is a circuit that transmits a ready/busy signal RBn to the memory controller 2 based on the control of the sequencer 14.

The voltage generator 16 generates voltages to be used for the write operation, read operation, and erase operation, based on the control of the sequencer 14. The voltage generator 16 supplies the generated voltages to the memory cell array 17, the row decoder 18, the sense amplifier 19, etc. The row decoder 18 and the sense amplifier 19 apply the voltages supplied from the voltage generator 16 to the memory cell array 17.

The memory cell array 17 is a set of a plurality of memory cell transistors (also simply referred to as “memory cells”) arranged in a matrix. The memory cell array 17 includes a plurality of blocks BLK. In the example shown a FIG. 1, the memory cell array 17 includes four blocks BLK0, BLK1, BLK2, and BLK3. The number of blocks BLK in the memory cell array 17 may be any number. The block BLK is, for example, a set of a plurality of memory cell transistors whose data is erased in a batch. That is, the block BLK is a unit of data erasure. The details of the configuration of the block BLK will be described later.

The row decoder 18 is a decode circuit for the row address RA. The row decoder 18 selects one block BLK in the memory cell array 17 based on a result of decoding. The row decoder 18 applies voltages to interconnects (word lines and select gate lines) in the row direction of the selected block BLK.

The sense amplifier 19 is a circuit that writes and reads data DAT. The sense amplifier 19 is coupled to the memory cell array 17 and the data register 20. In the read operation, the sense amplifier 19 reads data DAT from the memory cell array 17. In the write operation, the sense amplifier 19 supplies the memory cell array 17 with voltages based on the write data DAT and threshold voltages of the memory cell transistors.

The data register 20 is a register that temporarily stores the data DAT. The data register 20 is coupled to the sense amplifier 19 and the column decoder 21. The data register 20 includes a plurality of latch circuits. The latch circuits each temporarily store write data or read data.

The column decoder 21 is a circuit that decodes a column address CA. The column decoder 21 receives the column address CA from the address register 12. The column decoder 21 selects latch circuits in the data register 20 based on the result of decoding of the column address CA.

### 1. 1. 2 Circuit Configuration of Memory Cell Array

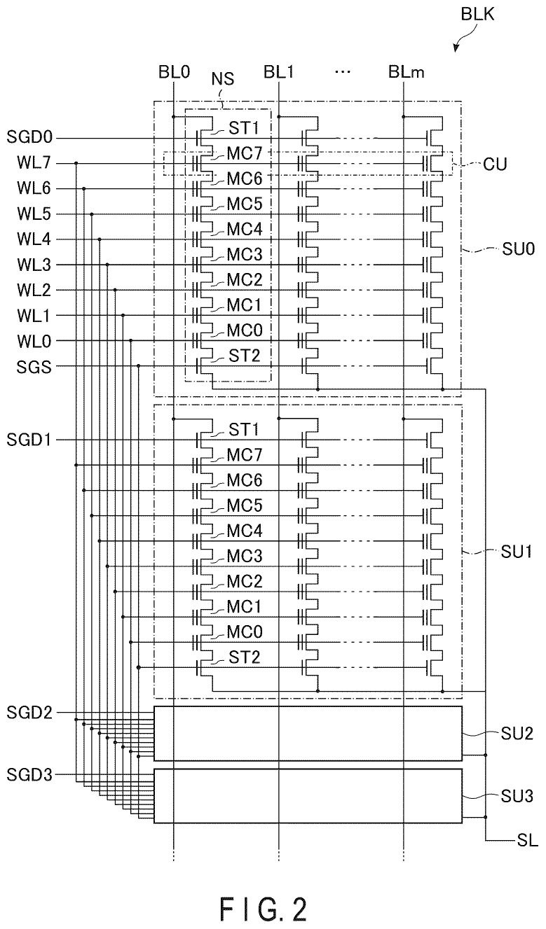

Next, an example of a circuit configuration of the memory cell array 17 will be described with reference to FIG. 2. FIG. 2 is a circuit diagram of the memory cell array 17.

The block BLK includes, for example, four string units SU0 through SU3. The number of string units SU included in the block BLK may be any number. The string unit SU is a set of a plurality of NAND strings NS that are collectively selected in the write operation or the read operation.

Next, an internal configuration of the string unit SU will be described. The string unit SU includes a plurality of NAND strings NS. Each NAND string NS is a set of memory cell transistors coupled in series. Each of the plurality of NAND strings NS in the string unit SU is coupled to any one of bit lines BL0 through BLm (m is an integer equal to or greater than 1).

Next, an internal configuration of the NAND string NS will be described. Each NAND string NS includes a plurality of memory cell transistors MC and select transistors ST1 and ST2. In the example shown in FIG. 2, the NAND string NS includes, for example, eight memory cell transistors MC0 through MC7.

Each of the memory cell transistors MC is a memory element that stores data in a non-volatile manner. The memory cell transistor MC includes a control gate and a charge storage layer. The memory cell transistor MC may be of a metal-oxide-nitride-oxide-silicon (MONOS) type, which uses an insulator as the charge storage layer, or of a floating-gate (FG) type, which uses a conductor as the charge storage layer. Hereinafter, the case in which the memory cell transistors MC are of the MONOS type will be described.

The select transistors ST1 and ST2 are switching elements. The select transistors ST1 and ST2 are each used for the selection of a string unit SU in various operations.

In each NAND string NS, current paths of the select transistor ST2, the memory cell transistors MC0 through MC7, and the select transistor ST1 are coupled in series. A drain of the select transistor ST1 is coupled to a bit line BL. A source of the select transistor ST2 is coupled to a source line SL.

The control gates of the memory cell transistors MC0 through MC7 in the same block BLK are respectively coupled in common to word lines WL0 through WL7. More specifically, the block BLK includes, for example, the four string units SU0 through SU3. Each string unit SU includes a plurality of memory cell transistors MC0. The control gates of the plurality of the memory cell transistors MC0 in the block BLK are coupled in common to one word line WL0. The same applies to the memory cell transistors MC1 through MC7.

The gates of the plurality of select transistors ST1 in the string unit SU are coupled in common to one select gate line SGD. Specifically, in the string unit SU0, the gates of the plurality of select transistors ST1 are coupled in common to a select gate line SGD0. The gates of the plurality of select transistors ST1 in the string unit SU1 are coupled in common to a select gate line SGD1. The gates of the plurality of select transistors ST1 in the string unit SU2 are coupled in common to a select gate line SGD2. The gates of the plurality of select transistors ST1 in the string unit SU3 are coupled in common to a select gate line SGD3.

The gates of the plurality the select transistors ST2 in the block BLK are coupled in common to a select gate line SGS. Similarly to the select gate line SGD, the select gate line SGS may be provided for each string unit SU.

The word lines WL0 through WL7, the select gate lines SGD0 through SGD3, and the select gate line SGS are coupled to the row decoder 18.

The bit lines BL are coupled in common to one NAND string NS in each string unit SU in each block BLK. Each bit line BL is coupled to the sense amplifier 19.

The source line SL is shared by, for example, a plurality of blocks BLK.

A set of the memory cell transistors MC coupled to a common word line WL in one string unit SU is referred to as, for example, a “cell unit CU”. In other words, the cell unit CU is a set of the memory cell transistors MC collectively selected in the write operation or the read operation. A page is a unit of data collectively written in (or collectively read from) the cell unit CU. For example, in a case where the memory cell transistor MC stores 1-bit data, the storage capacity of the cell unit CU is defined as 1-page data. The cell unit CU may have a storage capacity of two pages or more in accordance with the number of bits of data stored in the memory cell transistor MC.

### 1. 1. 3 Cross-Sectional Configuration of Memory Cell Array

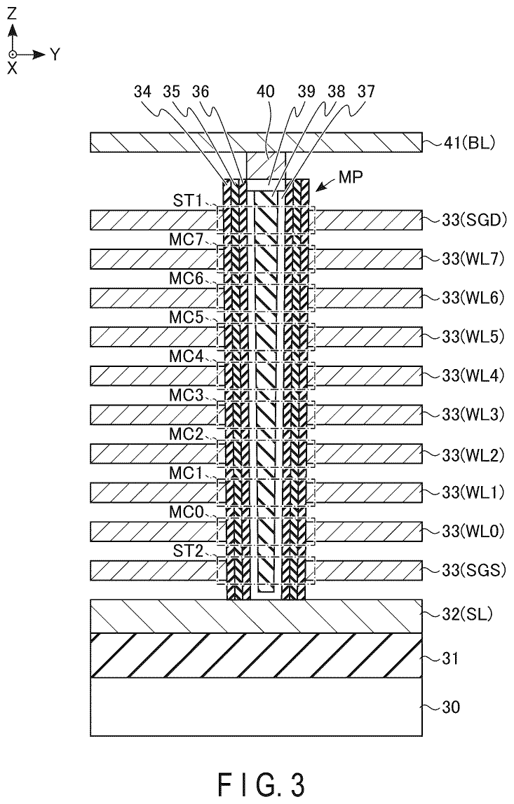

Next, an example of a cross-sectional configuration of the memory cell array 17 will be described with reference to FIG. 3. FIG. 3 is a sectional diagram of the memory cell array 17. FIG. 3 shows a cross section of one memory pillar MP corresponding to one NAND string NS. In FIG. 3, some interlayer insulating films are omitted.

As illustrated in FIG. 3, an insulating layer 31 is formed on a semiconductor substrate 30. For the insulating layer 31, for example, a silicon oxide (SiO) is used. Circuits such as the row decoder 18, the sense amplifier 19, or the like may be provided in a region where the insulating layer 31 is formed, that is, a region between the semiconductor substrate 30 and an interconnect layer 32.

The insulating layer 32 that spreads in an X direction substantially parallel to the semiconductor substrate 30 and a Y direction intersecting the X direction and that functions as a source line SL is formed on the insulating layer 31. The interconnect layer 32 is made of a conductive material, for example, a semiconductor material to which an impurity is added.

For example, ten interconnect layers 33, which function as the select gate line SGS, the word lines WL0 through WL7, and the select gate line SGD and extend in the X direction, are sequentially stacked one on another above the interconnect layer 32 with an interlayer insulating film (not shown) interposed therebetween.

Each interconnect layer 33 is made of a conductive material, for example, a semiconductor material to which an impurity is added, or a metal material. For example, a titanium nitride (TiN)/tungsten (W) stack structure is formed as the interconnect layer 33. Titanium nitride functions as a barrier layer to prevent reaction between tungsten and silicon oxide or as an adhesion layer to improve adhesion of tungsten, when tungsten is deposited by a chemical vapor deposition (CVD). The interconnect layer 33 may contain a high dielectric constant material, such as aluminum oxide (AlO). In this case, the high dielectric constant material is formed so as to cover the conductive material. For example, in each interconnect layer 33, the high dielectric constant material is provided so as to be in contact with a top surface and a bottom surface of the interconnect layer 33 and the side surface of a memory pillar MP. Titanium nitride is provided so as to be in contact with the high dielectric constant material. Tungsten is provided so as to be in contact with titanium nitride and embedded in the interior portion of the interconnect layer 33. For example, if aluminum oxide is provided as the high dielectric constant material, the memory cell transistor MC may be called a metal-aluminum-nitride-oxide-silicon (MANOS) type.

The memory pillar MP having a bottom surface that reaches the interconnect layer 32 is formed to pass through the ten interconnect layers 33. For example, the memory pillar MP has a cylindrical shape that extends in a Z direction. One memory pillar MP corresponds to one NAND string NS. The memory pillar MP includes a block insulating film 34, a charge storage layer 35, a tunnel insulating film 36, a semiconductor layer 37, a core layer 38, and a cap layer 39.

Specifically, a hole corresponding to the memory pillar MP is formed in such a manner as to pass through the interconnect layers 33 to have its bottom surface reach the interconnect layer 32. On the side surface of the hole, the block insulating film 34, the charge storage layer 35, and the tunnel insulating film 36 are sequentially stacked. The semiconductor layer 37, having a side surface that is in contact with the tunnel insulating film 36 and a bottom surface that reaches the interconnect layer 32, is formed. The semiconductor layer 37 is a region in which channels of the memory cell transistors MC and the select transistors ST1 and ST2 are to be formed. Therefore, the semiconductor layer 37 functions as a signal line that couples the current paths of the select transistor ST2, the memory cell memory transistors MC0 through MC7, and the select transistor ST1. The core layer 38 is provided inside the semiconductor layer 37. On the semiconductor layer 37 and the core layer 38, a cap layer 39 with a side surface in contact with the tunnel insulating film 36 is formed.

For the block insulating film 34, the tunnel insulating film 36, and the core layer 38, for example, silicon oxide is used. For the charge storage layer 35, for example, silicon nitride (SiN) is used. For the semiconductor layer 37 and the cap layer 39, for example, polysilicon is used.

A contact plug 40 is formed on the cap layer 39. An interconnect layer 41 that functions as a bit line BL and extends in the Y direction is formed on the contact plug 40. The contact plug 40 and the interconnect layer 41 are formed of a conductive material; for example, a copper (Cu) is used as the conductive material.

In the example of FIG. 3, one interconnect layer 33 is provided for each of the select gate lines SGD and SGS; however, a plurality of layers may be provided for each select gate line.

The memory cell transistors MC0 through MC7 are formed by the memory pillar MP, and eight interconnect layers 33 that respectively function as the word lines WL0 through WL7. Similarly, the select transistors ST1 and ST2 are formed by the memory pillar MP, and two interconnect layers 33 that respectively function as the select gate lines SGD and SGS.

### 1. 2 Threshold Voltage Distributions of Memory Cell Transistors

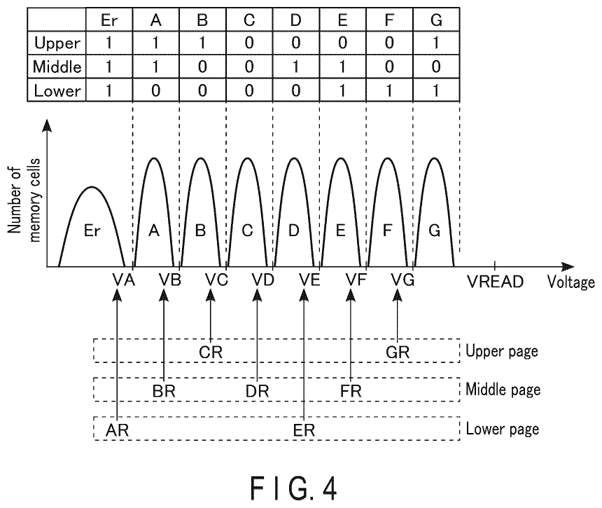

Next, an example of the threshold voltage distributions that the memory cell transistors MC may have will be described with reference to FIG. 4. FIG. 4 is a diagram showing threshold voltage distributions and data allocation in a case where each of the memory cell transistors MC is a triple level cell (TLC) which can store data of 3 bits (8 values). The number of bits which the memory cell transistor MC can store may be any number. For example, the memory cell transistor MC may be a single level cell (SLC) that can store data of 1 bit (two values), or may be a multi-level cell (MLC) that can store data of 2 bits (four values). Further, the memory cell transistor MC may be a quad level cell (QLC) that can store data of 4 bits (16 values), or may be a penta level cell (PLC) that can store data of 5 bits (32 values).

As illustrated in FIG. 4, if the memory cell transistor MC is a TLC, the threshold voltage of each memory cell transistor MC has a value included in, for example, any one of eight discrete distributions. The eight distributions are respectively referred to as an “Er” state, an “A” state, a “B” state, a “C” state, a “D” state, an “E” state, an “F” state, and a “G” state in ascending order of threshold voltage.

The “Er” state corresponds to, for example, a data erase state. The “A” through “G” states correspond to states in which charges are injected into the charge storage layer and data is written. In the write operation, verify voltages corresponding to the respective threshold voltage distributions are referred to as VA through VG. The values of the voltages satisfy the relation VA<VB<VC<VD<VE<VF<VG<VREAD. The voltage VREAD is a voltage applied to non-selected word lines WL in the read operation. When the voltage VREAD is applied to the gate of the memory cell transistor MC, the memory cell transistor MC is set to an ON state irrespective of the data stored therein. In the following explanations, a word line WL selected in the write operation or the read operation is referred to as a “selected word line WL_s”, and a word line WL that is not selected is referred to as a “non-selected word line WL_u”.

More specifically, the threshold voltage included in the “Er” state is lower than the voltage VA. The threshold voltage included in the “A” state is equal to or higher than the voltage VA and is lower than the voltage VB. The threshold voltage included in the “B” state is equal to or higher than the voltage VB and is lower than the voltage VC. The threshold voltage included in the “C” state is equal to or higher than the voltage VC and is lower than the voltage VD. The threshold voltage included in the “D” state is equal to or higher than the voltage VD and is lower than the voltage VE. The threshold voltage included in the “E” state is equal to or higher than the voltage VE and is lower than the voltage VF. The threshold voltage included in the “F” state is equal to or higher than the voltage VF and is lower than the voltage VG. The threshold voltage included in the “G” state is equal to or higher than the voltage VG and is lower than the voltage VREAD.

For example, the read voltages corresponding to the read operations of the “A” through “G” states are respectively referred to as VA through VG. These voltages and the voltage VREAD satisfy the relation VA<VB<VC<VD<VE<VF<VG<VREAD.

The setting value of the verify voltage and the setting value of the read voltage corresponding to each state may be the same or different. In the following, to simplify the explanation, a case is described in which the setting values of the verify voltage and the read voltage are the same.

Read operations corresponding to the “A” through “G” states are respectively referred to as an AR read operation, a BR read operation, a CR read operation, a DR read operation, an ER read operation, an FR read operation, and a GR read operation. The AR read operation determines whether or not the threshold voltage of the memory cell transistor MC is lower than the voltage VA. The BR read operation determines whether or not the threshold voltage of the memory cell transistor MC is lower than the voltage VB. The CR read operation determines whether or not the threshold voltage of the memory cell transistor MC is lower than the voltage VC. The same applies to the DR read operation, the ER read operation, the FR read operation, and the GR read operation.

As described above, each memory cell transistor MC can assume eight states in accordance with any one of the eight threshold voltage distributions. Each memory cell transistor MC can retain data of 3 bits by allocating these states to “000” through “111” in binary notation. In the following, the data of 3 bits are referred to as a “lower bit”, a “middle bit”, and an “upper bit”, respectively. Furthermore, a set of lower bits, middle bits, or upper bits collectively written in (or read from) a cell unit CU is referred to as a “lower page”, a “middle page”, or an “upper page”, respectively.

In the example of FIG. 4, data is allocated as follows to “upper bit/middle bit/lower bit” data for the memory cell transistor MC included in each threshold voltage distribution.
“Er” state: “111” data
“A” state: “110” data
“B” state: “100” data
“C” state: “000” data
“D” state: “010” data
“E” state: “011” data
“F” state: “001” data
“G” state: “101” data

In a case of reading data allocated as mentioned above, the lower bit is fixed by the AR read operation and the ER read operation. The middle bit is fixed by the BR read operation, the DR read operation, and the FR read operation. The upper bit is fixed by the CR read operation and the GR read operation. Thus, the values of the lower bit, the middle bit, and the upper bit are fixed by two read operations, three read operations, and two read operations, respectively. In the following, the data allocation described above is referred to as a “2-3-2 code”. The data allocation to the “Er” through “G” states is not limited to the “2-3-2 code”.

### 1. 3 Write Operation

Next, an example of a write operation will be described below. The write operation includes a program operation and a program verify operation. By repeating a combination of the program operation and the program verify operation (hereinafter referred to as a “program loop”), the threshold voltage of the memory cell transistor MC is increased to a target level.

The program operation is an operation that increases the threshold voltage by injection of electrons into the charge storage layer of a memory cell transistor MC of a target of programming (or that maintains the threshold voltage by inhibiting injection of electrons into the charge storage layer of a program-inhibited memory cell transistor MC).

The program verify operation is an operation of reading data from the memory cell transistor MC after the program operation and determining whether or not the threshold voltage of the memory cell transistor MC has reached a target level. The memory cell transistor MC whose threshold voltage has reached the target level is write-inhibited in the subsequent program loop.

### 1. 3. 1 Writing Order

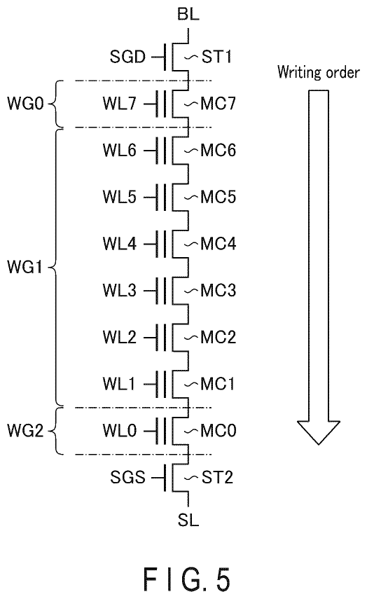

First, an example of an order of writing data in a NAND string NS will be described with reference to FIG. 5. FIG. 5 is a diagram showing an order of writing data in a NAND string NS.

As illustrated in FIG. 5, in a case of performing the write operation, memory cell transistors MC as targets of writing are sequentially selected from the memory cell transistor on the bit line BL side. Hereinafter, a memory cell transistor MC as a target of writing is referred to as a “selected memory cell transistor MC” or a “selected MC”. Note that, memory cell transistors as targets of writing may be sequentially selected from the memory cell transistor on the source line SL side.

In the example illustrated in FIG. 5, the sequencer 14 selects the word line WL7 first. Then, the sequencer 14 sequentially selects the word lines WL6 through WL1 in this order, and selects the word line WL0 last. In other words, the sequencer 14 selects the memory cell transistor MC7 first. Then, the sequencer 14 sequentially selects the memory cell transistors MC6 through MC1 in this order, and selects the memory cell transistor MC0 last. For example, a word line address corresponding to the word line WL7, which is selected first, is also referred to as a “first word line address”. A word line address corresponding to the word line WL0, which is selected last, is also referred to as a “last word line address”.

In the present embodiment, the word lines WL are divided into a plurality of word line groups WG based on the order of selecting the word lines WL. In the example illustrated in FIG. 5, the word lines WL0 through WL7 are divided into three word line groups WG0 through WG2. For example, the word line WL7 belongs to the word line group WG0. The word lines WL6 through WL1 belong to the word line group WG1. The word line WL0 belongs to the word line group WG2. That is, the word line WL corresponding to the first word line address belongs to the word line group WG0. The word lines WL corresponding to the word line addresses excluding the first word line address and the last word line address belong to the word line group WG1. The word line WL corresponding to the last word line address belongs to the word line group WG2. Note that, the number of word line groups WG may be four or more. Grouping of the word lines WL may be discretionarily set. For example, the word lines WL7 and WL6 may belong to the word line group WG0.

### 1. 3. 2 Relation Between Selection of Word Line Group and Write States of Memory Cell Transistors

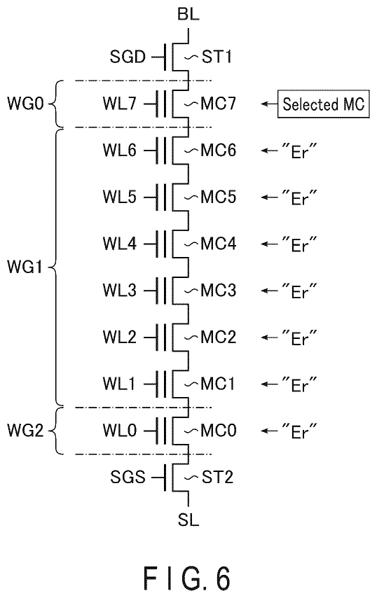

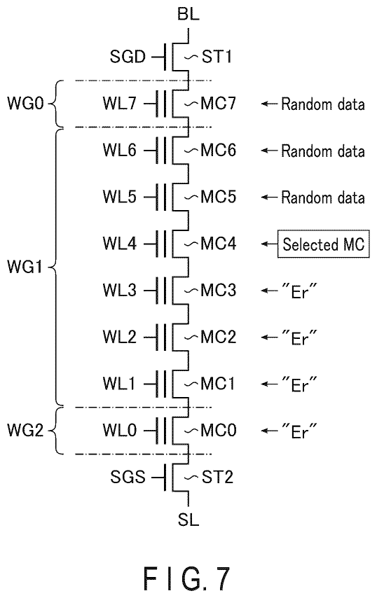

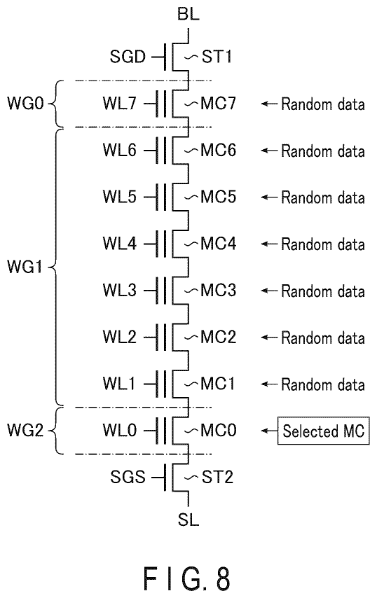

Next, an example of a relation between selection of the word line group WG and write states of the memory cell transistors MC will be described with reference to FIGS. 6 to 8. FIG. 6 is a diagram showing write states of the memory cell transistors MC when the word line group WG0 is selected. FIG. 7 is a diagram showing write states of the memory cell transistors MC when the word line group WG1 is selected. FIG. 7 shows a case in which the memory cell transistor MC4 (the word line WL4) is selected. FIG. 8 is a diagram showing write states of the memory cell transistors MC when the word line group WG2 is selected.

As illustrated in FIG. 6, in a case where the word line WL7 of the word line group WG0, that is, the memory cell transistor MC7, is selected, the non-selected memory cell transistors MC0 through MC6 are in an unwritten state in which the write operation has not been performed. That is, the non-selected memory cell transistors MC0 through MC6 are in the “Er” state.

As illustrated in FIG. 7, for example, in a case where the word line WL4 of the word line group WG1, that is, the memory cell transistor MC4, is selected, the non-selected memory cell transistors MC0 through MC3 are in the unwritten state. That is, the non-selected memory cell transistors MC0 through MC3 are in the “Er” state. Then, random data are written in the non-selected memory cell transistors MC5 through MC7. That is, the non-selected memory cell transistors MC5 through MC7 are in any one of the “Er” through “G” states.

As illustrated in FIG. 8, for example, in a case where the word line WL0 of the word line group WG2, that is, the memory cell transistor MC0 is selected, random data is written in the non-selected memory cell transistors MC1 through MC7. That is, the non-selected memory cell transistors MC1 through MC7 are in any one of the “Er” through “G” states.

### 1. 3. 3 Voltage of Each Interconnect in Write Operation

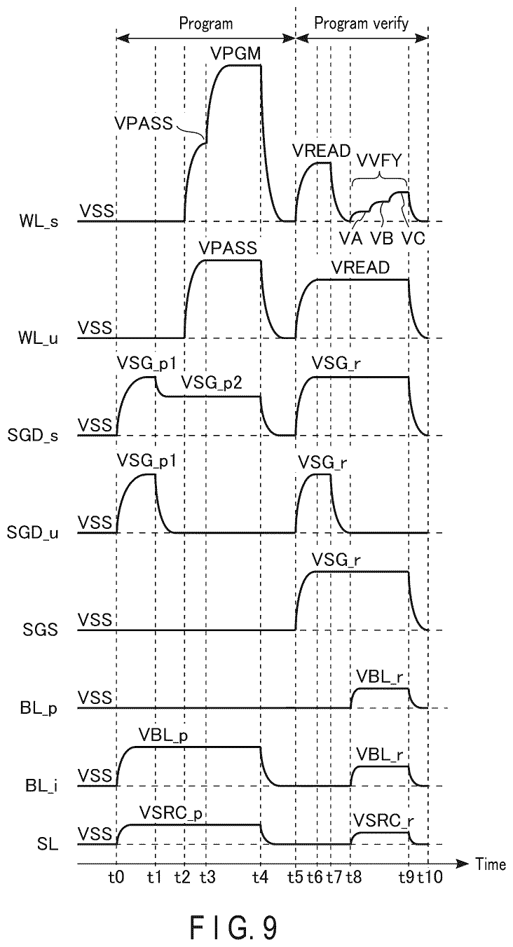

Next, an example of a voltage of each interconnect in the write operation will be explained with reference to FIG. 9. FIG. 9 is a timing chart showing a voltage of each interconnect in a program operation and a program verify operation. In the example illustrated in FIG. 9, a period between time t0 and time t5 represents the program operation, and a period between time t5 and time t10 represents the program verify operation.

In the following description, a string unit SU selected in the write operation is referred to as a “selected string unit SU”. The select gate line SGD corresponding to the selected string unit SU is referred to as a “select gate line SGD_s”. A string unit SU not selected in the write operation is referred to as a “non-selected string unit SU”. The select gate line SGD corresponding to the non-selected string unit SU is referred to as a “select gate line SGD_u”. Of the selected memory cell transistors MC, a bit line BL corresponding to a memory cell transistor MC which is a target of programming is referred to as a “bit line BL_p”. A bit line BL corresponding to a program-inhibited memory cell transistor MC is referred to as a “bit line BL_i”.

The program operation in the period between time t0 and time t5 will be described first.

As illustrated in FIG. 9, at time t0, the row decoder 18 applies a voltage VSG_p1 to the select gate lines SGD_s and SGD_u. The voltage VSG_p1 is a voltage that sets the select transistor ST1 in the ON state in the program operation. The sense amplifier 19 applies a voltage VBL_p to the bit line BL_i. The voltage VBL_p is higher than a voltage VSS and lower than the voltage VSG_p1. A voltage VSRC_p is applied to the source line SL. The voltage VSRC_p is a voltage higher than the voltage VSS. The select transistor ST1 in each string unit SU is set to the ON state. The select transistor ST2 is set to an OFF state.

At time t1, the row decoder 18 applies the voltage VSS to a select gate line SGS_u. Accordingly, the select transistor ST1 in the non-selected string unit SU is set to the OFF state. The decoder 18 also applies a voltage VSG_p2 to the select gate line SGD_s. The voltage VSG_p2 is higher than the voltage VSS and lower than the voltage VBL_p. Accordingly, the select transistor ST1 corresponding to the memory cell transistor MC which is a target of programming in the selected string unit SU is set to the ON state. The select transistor ST1 corresponding to the program-inhibited memory cell transistor MC is set to the OFF state. That is, the NAND string NS corresponding to the program-inhibited memory cell transistor MC is in a floating state.

At time t2, the row decoder 18 applies a voltage VPASS to a selected word line WL_s and non-selected word lines WL_u. The voltage VPASS is a voltage that sets the memory cell transistor MC to the ON state, irrespective of the threshold voltage of the memory cell transistor MC.

At time t3, the row decoder 18 applies a voltage VPGM to the selected word line WL_s. The voltage VPGM is a high voltage to inject electrons into the charge storage layer of the selected memory cell transistor MC which is a target of programming. The voltage VPGM is a voltage higher than the voltage VPASS. Accordingly, in the selected memory cell transistor MC which is a target of programming, a potential difference between the selected word line WL_s and a channel (VPGM-VSS) is increased. As a result, electrons are injected into the charge storage layer, and the threshold voltage of the selected memory cell transistor MC is increased. On the other hand, in the program-inhibited selected memory cell transistor MC, a potential difference between the selected word line WL_s and a channel is smaller than that in the memory cell transistor MC which is a target of programming due to a channel boost. As a result, substantially no electrons are injected into the charge storage layer, and the threshold voltage of the memory cell transistor MC is maintained (the threshold voltage does not change so much as to transition to a threshold voltage distribution in which the threshold voltage is higher). Note that, the voltage VPGM may be stepped up each time the program loop is repeated.

In a period between time t4 and time t5, the row decoder 18 discharges voltages that have been applied to the selected word line WL_s, the non-selected word lines WL_u, and the select gate line SGD_s. In the example illustrated in FIG. 9, the potentials of the selected word line WL_s, the non-selected word lines WL_u, and the select gate line SGD_s are dropped to the voltage VSS. Note that, the potentials of the selected word line WL_s and the non-selected word lines WL_u at time t5 may be higher than the voltage VSS. The sense amplifier 19 applies the voltage VSS to the bit line BL_i. The voltage VSS is also applied to the source line SL.

Next, the program verify operation in the period between time t5 and t10 will be described.

First, at time t5, the row decoder 18 applies the voltage VREAD to the selected word line WL_s and the non-selected word lines WL_u. The row decoder 18 applies a voltage VSG_r to the select gate lines SGD_s, SGD_u, and SGS. The voltage VSG_r is a voltage that sets the select transistors ST1 and ST2 in the ON state in the program verify operation.

In a period between time t5 and time t6, the voltage applied to the selected word line WL_s and the non-selected word lines WL_u reaches the voltage VREAD. The period between time t5 and time t6 is also referred to as a “setup time (boost time)” of the voltage VREAD.

At time t7, the row decoder 18 applies the voltage VSS to the selected word line WL_s and the select gate line SGD_u. Accordingly, the selected memory cell transistor MC in the selected string unit SU and the select transistor ST1 in the non-selected string unit SU is set to the OFF state.

In a period between time t8 and t9, the row decoder 18 applies a voltage VVFY to the selected word line WL_s. The voltage VVFY is a voltage applied to the selected word line WL in the program verify operation. The voltage VVFY is lower than the voltage VREAD. The voltage VVFY is based on a target level (write target state) of the write operation. In the example illustrated in FIG. 9, the row decoder 18 applies, as the voltage VVFY, the voltages VA, VB, and VC sequentially to the selected word line WL_s in this order. In other words, the sequencer 14 sequentially performs the AR read operation, the BR read operation, and the CR read operation. The sense amplifier 19 applies a voltage VBL_r to the bit lines BL_p and BL_i. A voltage VSRC_r is applied to the source line SL. The voltage VSRC_r is a voltage higher than the voltage VSS and lower than the voltage VBL_r.

In the period between time t8 and t9, the sense amplifier 19 reads data from the selected memory cell transistors MC. In a case where the threshold voltage of a memory cell transistor MC is equal to or higher than the voltage VVFY, the memory cell transistor MC is in the OFF state. In this case, the sequencer 14 determines that the write operation in the memory cell transistor MC has been completed. On the other hand, in a case where the threshold voltage of a memory cell transistor MC is lower than the voltage VVFY, the memory cell transistor MC is in the ON state. In this case, the sequencer 14 determines that the write operation in the memory cell transistor MC has not been completed.

In a period between time t9 and t10, the voltages of the interconnects of the selected word line WL_s, the non-selected word lines WL_u, the select gate lines SGD_s, SGD_u, and SGS, the bit lines BL_p and BL_i, and the source line SL are discharged. That is, the voltage VSS is applied to all the interconnects.

### 1. 3. 4 Voltage and Current of Non-Selected Word Lines in Program Verify Operation

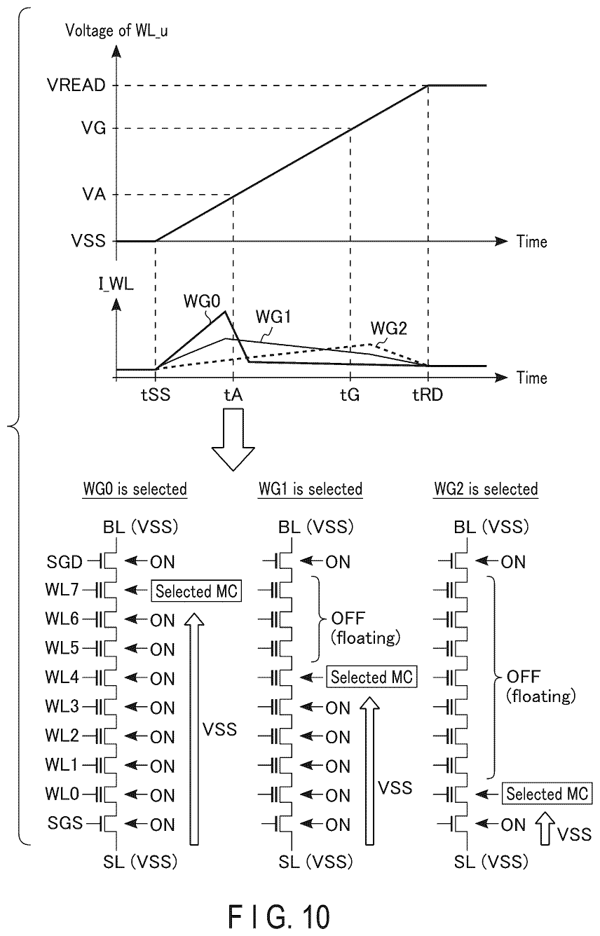

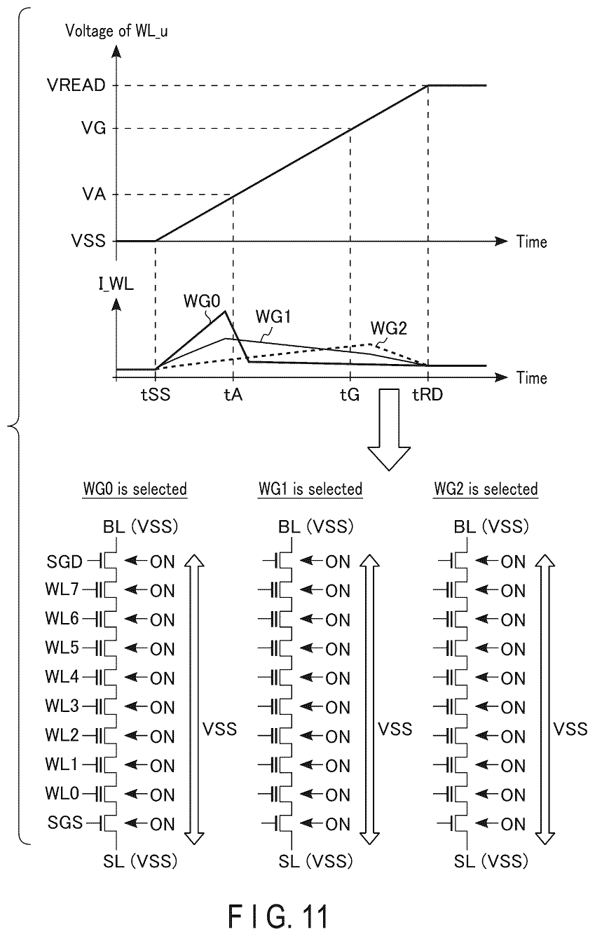

Next, an example of the voltage and current of the non-selected word lines WL_u in the program verify operation will be described with reference to FIGS. 10 and 11. Each of FIGS. 10 and 11 is a timing chart showing a voltage and a current I_WL of the non-selected word lines WL_u in the program verify operation and a diagram showing a comparison example of states of NAND strings NS. FIGS. 10 and 11 show a case in which the voltage of the non-selected word lines WL_u rises (increases) at a constant increase rate (slew rate), irrespective of a word line group WG that is selected (hereinafter referred to as a “selected word line group WG”). FIG. 10 shows an example of the state of the NAND string NS in a case where the voltage of the non-selected word lines WL_u is the voltage VA. FIG. 11 shows an example of the state of the NAND string NS in a case where the voltage of the non-selected word lines WL_u is higher than the voltage VG. In FIGS. 10 and 11, the current I_WL in a case where the word line group WG0 is selected is represented by a thick solid line. The current I_WL in a case where the word line group WG1 is selected is represented by a thin solid line. The current I_WL in a case where the word line group WG2 is selected is represented by a thick broken line.

As illustrated in FIGS. 10 and 11, for example, in the program verify operation, the voltage of the non-selected word lines WL_u in a period between time tSS and time tRD (setup time) increases from the voltage VSS to the voltage VREAD. For example, irrespective of the selected word line group WG, if the increase rate of the voltage applied to the non-selected word lines WL_u is constant, the peak value of the current I_WL flowing through the non-selected word lines WL_u is maximized in a case where the word line group WG0 is selected.

When the voltage of the non-selected word lines WL_u is increased and the voltage of the non-selected word lines WL_u becomes higher than the threshold voltage of the non-selected memory cell transistor MC, the non-selected memory cell transistor MC transitions from the OFF state to the ON state. The timing at which the non-selected memory cell transistor MC transitions to the ON state varies depending on the threshold voltage (state) of the non-selected memory cell transistor MC. When the non-selected memory cell transistor MC is in the ON state and the channel of this memory cell transistor MC is electrically conductive to the source line SL or the bit line BL, parasitic capacitance between the gate and the channel of the memory cell transistor MC needs to be charged when increasing the voltage of the non-selected word lines WL_u. Therefore, the amount of current necessary to increase the voltage of the non-selected word lines WL_u is increased. In a plurality of non-selected memory cell transistors MC included in the selected string unit SU, the nearer the timings at which charging of the parasitic capacitance starts in the memory cell transistors MC become to each other, the more the peak value of the current I_WL increases.

For example, in a case where the memory cell transistor MC7 in the word line group WG0 is selected, the non-selected memory cell transistors MC0 through MC6 are all in the “Er” state. At time tA, when the voltage applied to the non-selected word lines WL_u reaches the voltage VA, the non-selected memory cell transistors MC0 through MC6 are all in the ON state. Since the select transistors ST1 and ST2 are in the ON state, the channels of the non-selected memory cell transistors MC0 through MC6 are electrically conductive to the source line SL. Therefore, the non-selected memory cell transistors MC0 through MC6 in the selected string unit SU are brought to be electrically conductive at substantially the same timing (including a timing shift corresponding to the threshold voltage distribution). That is, the non-selected memory cell transistors MC0 through MC6 start charging of the parasitic capacitance at substantially the same timing.

In a case where the word line group WG0 is selected, the charging of the parasitic capacitances of the non-selected memory cell transistors MC0 through MC6 of the selected string unit SU starts at substantially the same timing. Therefore, as compared to a case in which the word line group WG1 or WG2 is selected, the peak value of the current I_WL is the highest.

As, for example, in a case where the memory cell transistor MC4 in the word line group WG1 is selected, the non-selected memory cell transistors MC0 through MC3 are in the “Er” state. The non-selected memory cell transistors MC5 through MC7 are in any of the “Er” through “G” states. For example, at time tA, the non-selected memory cell transistors MC0 through MC3 are in the ON state and electrically conductive to the source line SL. On the other hand, the non-selected memory cell transistors MC5 through MC7 maintain the OFF state if they are not in the “Er” state. In most of the NAND strings NS in the selected string unit SU, the non-selected memory cell transistors MC5 through MC7 are in the floating state. The timings when the non-selected memory cell transistors MC5 through MC7 are turned to the ON state vary depending on the difference in state. Therefore, the timings when the non-selected memory cell transistors MC5 through MC7 are electrically conductive to the bit line BL vary. That is, the non-selected memory cell transistors MC0 through MC3 start charging of the parasitic capacitances at substantially the same timing. On the other hand, the timings when the non-selected memory cell transistors MC5 through MC7 start charging of the parasitic capacitances vary. As illustrated in FIG. 11, when the voltage of the non-selected word lines WL_u is higher than the voltage VG and the memory cell transistor MC in the “G” state is set to the ON state, the non-selected memory cell transistor MC5 through MC7 are set to the ON state and electrically conductive to the source line SL.

For example, in a case where the memory cell transistor MC0 in the word line group WG2 is selected, the non-selected memory cell transistors MC1 through MC7 are in any of the “Er” through “G” states. For example, at time tA, the non-selected memory cell transistors MC1 through MC7 maintain the OFF state, if they are not in the “Er” state. In most of the NAND strings NS in the selected string unit SU, the non-selected memory cell transistors MC1 through MC7 are in the floating state. The timings when the non-selected memory cell transistors MC1 through MC7 are turned to the ON state vary depending on the difference in state. Therefore, the timings when the non-selected memory cell transistors MC1 through MC7 are electrically conductive to the bit line BL vary. That is, the timings when the non-selected memory cell transistors MC1 through MC7 start charging of the parasitic capacitances vary. As illustrated in FIG. 11, when the voltage of the non-selected word lines WL_u is higher than the voltage VG and the memory cell transistor MC in the “G” state is set to the ON state, the non-selected memory cell transistor MC1 through MC7 are set to the ON state and become electrically conductive to the source line SL.

### 1. 3. 5 Conditions for Setup of Non-Selected Word Lines in Program Verify Operation

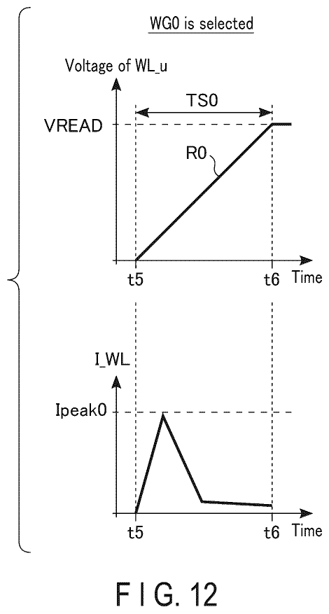

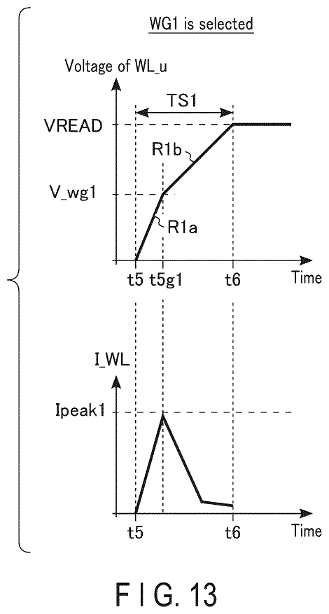

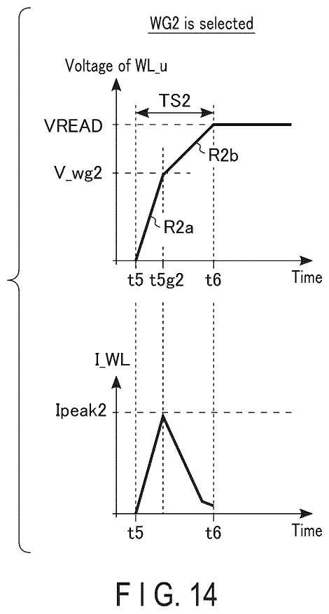

Next, an example of conditions for setup of the non-selected word lines WL_u in the program verify operation will be described with reference to FIGS. 12 to 14. FIG. 12 is a diagram showing a voltage and a current of the non-selected word lines WL_u in the period between time t5 and time t6 described with reference to FIG. 9, in a case where the word line group WG0 is selected. FIG. 13 is a diagram showing a voltage and a current of the non-selected word lines WL_u in the period between time t5 and time t6 described with reference to FIG. 9, in a case where the word line group WG1 is selected. FIG. 14 is a diagram showing a voltage and a current of the non-selected word lines WL_u in the period between time t5 and time t6 described with reference to FIG. 9, in a case where the word line group WG2 is selected.

In the present embodiment, conditions for setup (conditions for boosting) to raise the voltage of the non-selected word lines WL_u to the voltage VREAD vary depending on the selected word line group WG. More specifically, different conditions for applying the voltage VREAD are set to the respective selected word line groups WG, so that setup time TS (the length of the period between time t5 and time t6 in FIG. 9) is shorter in ascending order of the word line groups WG0, WG1, and WG2.

For example, as described above with reference to FIGS. 10 and 11, if the increase rate R of the voltage VREAD is constant, a peak value Ipeak of the current I_WL in a case where the word line group WG1 or WG2 is selected is smaller than a peak value Ipeak of the current I_WL in a case where the word line group WG0 is selected. Therefore, in the present embodiment, in the case where the word line group WG1 or WG2 is selected, a step of increasing the increase rate R of the voltage VREAD is added until the peak value Ipeak of the current I_WL becomes substantially equal to the peak value Ipeak of the current I_WL in the case where the word line group WG0 is selected, thereby shortening the setup time TS in the case where the word line group WG1 or WG2 is selected.

First, conditions for setup of the voltage VREAD in the case where the word line group WG0 is selected will be described.

As illustrated in FIG. 12, in a case where the word line group WG0 is selected, between time t5 and time t6, the row decoder 18 raises the voltage of the non-selected word lines WL_u at a constant increase rate R0 to the voltage VREAD. The setup time at this time (the length of the period between time t5 and t6) is assumed to be TS0. For example, the setup time TS0 is set to a time in which the peak value Ipeak0 of the word line current I_WL does not exceed a preset upper limit value.

Next, conditions for setup of the voltage VREAD in the case where the word line group WG1 is selected will be described.

As illustrated in FIG. 13, in a case where the word line group WG1 is selected, the row decoder 18 raises the voltage of the non-selected word lines WL_u in two steps to the voltage VREAD in the period between time t5 and time t6. The number of steps may be three or more.

First, as a first step, in a period between time t5 and time t5g1, the row decoder 18 raises the voltage of the non-selected word lines WL_u to a voltage V_wg1. For example, at time t5g1, the current I_WL becomes a peak value Ipeak1. The voltage V_wg1 is, for example, a voltage higher than the voltage VA and lower than the voltage VREAD. The increase rate of the voltage at this time is assumed to be R1a. The increase rates R0 and R1a satisfy the relation of R0<R1a. For example, by changing the increase rate of the voltage from R0 to R1a, in the period between time t5 and time t5g1, the number of non-selected memory cell transistors MC that are in the ON state among the non-selected memory cell transistors MC storing random data (any of the “Er” through “G” states) is increased. That is, in the period between time t5 and time t5g1, the number of non-selected memory cell transistors MC that are electrically conductive to the bit line BL is increased. Therefore, the peak value Ipeak1 of the current I_WL is increased. The voltage V_wg1 and the increase rate R1a are set so that, for example, the peak value Ipeak1 of the current I_WL is substantially equal to the peak value Ipeak0 of the current I_WL in the case where the word line group WG0 is selected.

Next, as a second step, in a period between time t5g1 and time t6, the row decoder 18 raises the voltage of the non-selected word lines WL_u from the voltage V_wg1 to the voltage VREAD. The increase rate of the voltage at this time is assumed to be R1b. For example, the increase rates R0 and R1b satisfy the relation of R0=R1b. Note that, the increase rates R0 and R1b may satisfy the relation of R0>R1b, or the relation of R0<R1b.

The setup time (the length of the period between time t5 and t6) in the case where the word line group WG1 is selected is assumed to be TS1. The setup times TS0 and TS1 satisfy the relation of TS0>TS1. That is, in the case where the word line group WG1 is selected, the setup time of the voltage VREAD can be shorter than that in the case where the word line group WG0 is selected.

Next, conditions for setup of the voltage VREAD in the case where the word line group WG2 is selected will be described.

As illustrated in FIG. 14, in the case where the word line group WG2 is selected, similarly to the case where the word line group WG1 is selected, the row decoder 18 raises the voltage of the non-selected word lines WL_u in two steps to the voltage VREAD in the period between time t5 and time t6. Note that, the number of steps may be three or more.

First, as a first step, in a period between time t5 and time t5g2, the row decoder 18 raises the voltage of the non-selected word lines WL_u to a voltage V_wg2. For example, at time t5g2, the current I_WL becomes a peak value Ipeak2. The length of the period between time t5 and time t5g2 may be equal to or different from the length of the period between time t5 and time t5g1. The voltage V_wg2 is, for example, a voltage higher than the voltage V_wg1 and lower than the voltage VREAD. The voltage V_wg2 is set so that the peak value Ipeak2 of the current I_WL is substantially equal to the peak value Ipeak0 of the current I_WL in the case where the word line group WG0 is selected. For example, the voltages V_wg1 and V_wg2 and the increase rates R1a and R2a are set so that the peak value Ipeak0 of the current I_WL in the case where the word line group WG0 is selected, the peak value Ipeak1 of the current I_WL in the case where the word line group WG1 is selected, and the peak value Ipeak2 of the current I_WL in the case where the word line group WG2 is selected are substantially equal. As a result, the variation of the peak value Ipeak of the current I_WL depending on the selected word line WL can be reduced in the semiconductor memory device 1.

The increase rate of the voltage in the first step is assumed to be R2a. The increase rates R0, R1a, and R2a satisfy the relation of R0<R1a<R2a. In the case where the word line group WG2 is selected, all the non-selected memory cell transistors MC store random data. In the period between time t5 and time t5g2, to increase the number of non-selected memory cell transistors MC that are in the ON state and are electrically conductive to the bit line BL, the increase rate R2a is set higher than the increase rate R1a.

Next, as a second step, in a period between time t5g2 and time t6, the row decoder 18 raises the voltage of the non-selected word lines WL_u from a voltage V_wg2 to the voltage VREAD. The increase rate of the voltage at this time is assumed to be R2b. The increase rates R0 and R2b satisfy the relation of R0=R2b. Note that, the increase rates R0 and R2b may satisfy the relation of R0>R2b, or the relation of R0<R2b.

The setup time (the length of the period between time t5 and t6) in the case where the word line group WG2 is selected is assumed to be TS2. The setup times TS0, TS1, and TS2 satisfy the relation of TS0>TS1>TS2. That is, in the case where the word line group WG2 is selected, the setup time of the voltage VREAD can be shorter than that in the case where the word line group WG0 or WG1 is selected.

### 1. 4 Advantages of Present Embodiment

With the configuration according to the present embodiment, the semiconductor memory device 1 can group a plurality of word lines WL coupled to one NAND string NS (block BLK). For example, the semiconductor memory device 1 can group the word lines WL into the word line group WG0 to which a word line WL corresponding to the first word line address belongs, the word line group WG1 to which word lines WL corresponding to another word line address excluding the first word line address and the last word line address belongs, and the word line group WG2 to which a word line WL corresponding to the last word line address belongs. The semiconductor memory device 1 can raise the voltage of the non-selected word lines WL_u to the voltage VREAD in different conditions for setup on the respective selected word line groups WG in the program verify operation. For example, the semiconductor memory device 1 can raise the voltage of the non-selected word lines WL_u to the voltage VREAD in two steps in the case where the word line group WG1 or WG2 is selected. More specifically, the semiconductor memory device 1 can set the increase rate R1a of the voltage in the first step of the conditions for setup in the case where the word line group WG1 is selected to be higher than the increase rate R0 of the voltage of the conditions for setup in the case where the word line group WG0 is selected. Accordingly, the semiconductor memory device 1 can set the setup time TS1 of the voltage VREAD in the case where the word line group WG1 is selected to be shorter than the setup time TS0 of the voltage VREAD in the case where the word line group WG0 is selected. In addition, the semiconductor memory device 1 can set the increase rate R2a of the voltage in the first step in the case where the word line group WG2 is selected to be higher than the increase rate R1a. Accordingly, the semiconductor memory device 1 can set the setup time TS2 of the voltage VREAD in the case where the word line group WG2 is selected to be shorter than the setup time TS1. Thus, the semiconductor memory device 1 can shorten the process time of the write operation and improve the processing capacity.

Furthermore, with the configuration of the present embodiment, the semiconductor memory device 1 can suppress the variation of the currents I_WL in the respective word line groups WG.

### 2. Second Embodiment

Next, a second embodiment will be described. In the second embodiment, a case is described in which conditions for setup of the non-selected word lines WL in the program verify operation are different from those in the first embodiment. Hereinafter, differences from the first embodiment will be mainly described.

### 2. 1 Conditions for Setup of Non-Selected Word Lines in Program Verify Operation

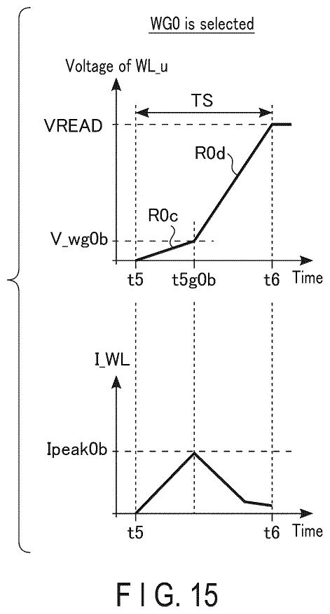

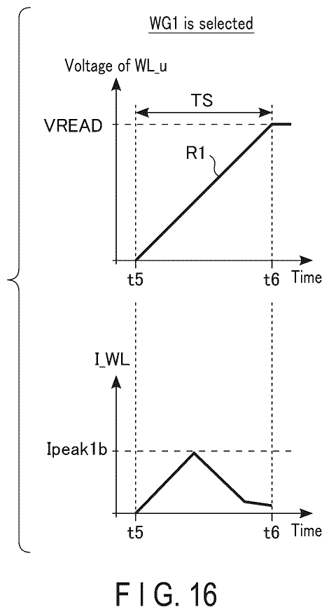

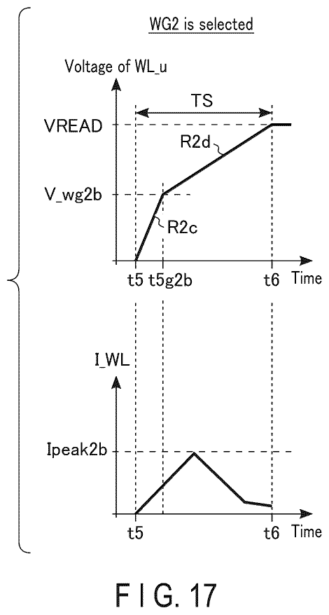

An example of a boosting operation of the non-selected word lines WL_u in the program verify operation according to the present embodiment will be described with reference to FIGS. 15 through 17. FIG. 15 is a diagram showing a voltage and a current of the non-selected word lines WL_u in the period between time t5 and time t6 described with reference to FIG. 9, in a case where the word line group WG0 is selected. FIG. 16 is a diagram showing a voltage and a current of the non-selected word lines WL_u in the period between time t5 and time t6 described with reference to FIG. 9, in a case where the word line group WG1 is selected. FIG. 17 is a diagram showing a voltage and a current of the non-selected word lines WL_u in the period between time t5 and time t6 described with reference to FIG. 9, in a case where the word line group WG2 is selected.

In the present embodiment, the setup time TS of the voltage VREAD is the same, irrespective of the selected word line group WG. Conditions for setup of the voltage VREAD are different depending on the selected word line group WG.

In the present embodiment, in the case where the word line group WG0 is selected, the peak value Ipeak of the current I_WL is reduced by adding a step in which the increase rate R of the voltage VREAD is reduced. Furthermore, in the case where the word line group WG2 is selected, the variation of the peak values Ipeak of the current I_WL in the respective word line groups WG is reduced by adding a step in which the increase rate R of the voltage VREAD is increased.

First, conditions for setup of the voltage VREAD in the case where the word line group WG0 is selected will be described.

As illustrated in FIG. 15, in a case where the word line group WG0 is selected, the row decoder 18 raises the voltage of the non-selected word lines WL_u in two steps to the voltage VREAD in the period between time t5 and time t6. Note that, the number of steps may be three or more.

First, as a first step, in a period between time t5 and time t5g0b, the row decoder 18 raises the voltage of the non-selected word lines WL_u to a voltage V wg0b. For example, at time t5g0b, the current I_WL becomes a peak value Ipeak0b. For example, the voltage V_wg0b is a voltage equal to or lower than the voltage VA. The increase rate of the voltage at this time is assumed to be R0c. The increase rate R0c is lower than the increase rate in a case where the voltage of the non-selected word lines WL_u rises to the voltage VREAD at a constant rate in the period between time t5 and time t6. The peak value Ipeak0b of the current I_WL can be reduced by lowering the increase rate.

Next, as a second step, in a period between time t5g0b and time t6, the row decoder 18 raises the voltage of the non-selected word lines WL_u from a voltage V_wg0b to the voltage VREAD. The increase rate of the voltage at this time is assumed to be R0d. The increase rates R0c and R0d satisfy the relation of R0c<R0d. The increase rate R0d is higher than the increase rate in the case where the voltage of the non-selected word lines WL_u rise to the voltage VREAD at a constant rate in the period between time t5 and time t6.

Next, conditions for setup of the voltage VREAD in the case where the word line group WG1 is selected will be described.

As illustrated in FIG. 16, in a case where the word line group WG1 is selected, between time t5 and time t6, the row decoder 18 raises the voltage of the non-selected word lines WL_u at a constant increase rate R1 to the voltage VREAD. For example, the increase rate R1 is set so that the peak value Ipeak1b of the word line current I_WL does not exceed a preset upper limit value. The increase rate R1 is higher than the increase rate R0c and lower than the increase rate R0d. For example, the increase rate R0c is set so that the peak value Ipeak0b and the peak value Ipeak1b are substantially equal.

Next, conditions for setup of the voltage VREAD in the case where the word line group WG2 is selected will be described.

As illustrated in FIG. 17, in the case where the word line group WG2 is selected, similarly to the case where the word line group WG0 is selected, the row decoder 18 raises the voltage of the non-selected word lines WL_u in two steps to the voltage VREAD in the period between time t5 and time t6. Note that, the number of steps may be three or more.

First, as a first step, in a period between time t5 and time t5g2b, the row decoder 18 raises the voltage of the non-selected word lines WL_u to a voltage V_wg2b. The length of the period between time t5 and time t5g2b may be equal to or different from the length of the period between time t5 and time t5g0b. The voltage V_wg2b is, for example, a voltage higher than the voltage V_wg0b and lower than the voltage VREAD. The increase rate of the voltage at this time is assumed to be R2c. The increase rate R2c is, for example, higher than the increase rate R1.

Next, as a second step, in a period between time t5g2b and time t6, the row decoder 18 raises the voltage of the non-selected word lines WL_u from the voltage V_wg2b to the voltage VREAD. The increase rate of the voltage at this time is assumed to be R2d. The increase rate R2d is lower than the increase rate R2c in the first step. For example, the increase rate R2d is set so that the peak value Ipeak2b of the word line current I_WL does not exceed a preset upper limit value. For example, the increase rate R2d is set so that the peak value Ipeak2b and the peak value Ipeak1b are substantially equal. For example, the increase rate R2d and the increase rate R1 satisfy the relation of R2d<R1.

### 2. 2 Advantages of Present Embodiment

With the configuration according to the present embodiment, similarly to the first embodiment, the semiconductor memory device 1 can group a plurality of word lines WL coupled to one NAND string NS (block BLK). Also, the semiconductor memory device 1 can raise the voltage of the non-selected word lines WL_u to the voltage VREAD in different conditions for setup on the respective selected word line groups WG in the program verify operation. For example, the semiconductor memory device 1 can reduce the peak value Ipeak0b of the current I_WL by lowering the increase rate R0c of the voltage in the first step of conditions for setup, in the case where the word line group WG0 is selected. Accordingly, the peak value Ipeak of consumption current in the semiconductor memory device 1 can be reduced. In addition, the semiconductor memory device 1 can set the increase rate R0d of the voltage in the second step of conditions for setup to be higher than the increase rate R0c of the voltage in the first step of conditions for setup, in the case where the word line group WG0 is selected. Accordingly, the semiconductor memory device 1 can shorten the setup time TS.

Furthermore, with the configuration of the present embodiment, the semiconductor memory device 1 can set the increase rate R2c of the voltage in the first step of conditions for setup to be high to increase the peak value Ipeak2b of the current I_WL, in the case where the word line group WG2 is selected. Accordingly, the semiconductor memory device 1 can suppress the variation of the currents I_WL in the respective word line groups WG.

Moreover, with the configuration of the present embodiment, the semiconductor memory device 1 can raise the voltage of the non-selected word lines WL_u to the voltage VREAD in two steps in the case where the word line group WG0 or WG2 is selected. Accordingly, the increase in the setup time TS can be suppressed. Therefore, the semiconductor memory device 1 can suppress the increase in process time of the write operation.

### 3. Modifications

According to the above embodiments, a semiconductor memory device includes a memory string including a first select transistor (ST1), a first memory cell (MC7), and a second memory cell (MC6) which are coupled in series, a bit line (BL) coupled to the first select transistor, a first word line (WL7) coupled to the first memory cell, a second word line (WL6) coupled to the second memory cell, and a control circuit (14) configured to execute a write operation including a program operation and a program verify operation. The control circuit is configured to raise a voltage of the second word line to a first voltage (VREAD) based on a first condition, in a case of executing the program verify operation of the first memory cell, and to raise a voltage of the first word line to the first voltage based on a second condition different from the first condition, in a case of executing the program verify operation of the second memory cell.

The configuration according to the embodiments described above can improve the process capacity.

The above-described embodiments are merely examples, and can be modified in various manners.

For example, in the above embodiments, the case is described in which conditions for setup of the non-selected word lines WL in the program verify operation are different for the respective word line groups WG in the program verify operation. However, similar conditions for setup may be applied to the read operation.

Furthermore, the term “couple” in the above-described embodiments also includes the state of indirect coupling with other components, such as a transistor and a resistor, interposed therebetween.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory string including a first select transistor, a first memory cell, and a second memory cell which are coupled in series;
a bit line coupled to the first select transistor;
a first word line coupled to the first memory cell;
a second word line coupled to the second memory cell; and
a control circuit configured to execute a write operation including a program operation and a program verify operation, wherein
the control circuit is configured to:
raise a voltage of the second word line to a first voltage based on a first condition, in a case of executing the program verify operation of the first memory cell; and
raise a voltage of the first word line to the first voltage based on a second condition different from the first condition, in a case of executing the program verify operation of the second memory cell.

2. The semiconductor memory device according to claim 1, wherein the control circuit is further configured to execute the write operation of the second memory cell after the write operation of the first memory cell.

3. The semiconductor memory device according to claim 1, wherein a first period in which the first condition is executed is longer than a second period in which the second condition is executed.

4. The semiconductor memory device according to claim 3, wherein
the second condition includes a first step executed first and a second step executed subsequent to the first step, and
a first increase rate of the first voltage in the first step is higher than a second increase rate of the first voltage in the first condition.

5. The semiconductor memory device according to claim 4, wherein a third increase rate of the first voltage in the second step is equal to the second increase rate.

6. The semiconductor memory device according to claim 1, further comprising:
a source line; and
a third word line, wherein
the memory string further includes:
a third memory cell electrically coupled to the second memory cell; and
a second select transistor coupled to the third memory cell in series,
the source line is coupled to the second select transistor,
the third word line is coupled to the third memory cell, and
the control circuit is further configured to raise the voltage of the first word line and the voltage of the second word line to the first voltage based on a third condition different from the first condition and the second condition, in a case of executing the program verify operation of the third memory cell.

7. The semiconductor memory device according to claim 6, wherein the control circuit is configured to execute the write operation of the third memory cell after the write operation of the second memory cell.

8. The semiconductor memory device according to claim 6, wherein a third period in which the third condition is executed is shorter than the second period in which the second condition is executed.

9. The semiconductor memory device according to claim 6, wherein:
the second condition includes a first step executed first and a second step executed subsequent to the first step;
the third condition includes a third step executed first and a fourth step executed subsequent to the third step; and
a first increase rate of the first voltage in the first step is higher than a fourth increase rate of the first voltage in the third step.

10. The semiconductor memory device according to claim 9, wherein a fifth increase rate of the first voltage in the fourth step is equal to a second increase rate of the first voltage in the first condition.

11. The semiconductor memory device according to claim 1, wherein a first period in which the first condition is met is equal in length to a second period in which the second condition is met.

12. The semiconductor memory device according to claim 11, wherein:
the first condition includes a first step executed first and a second step executed subsequent to the first step; and
a first increase rate of the first voltage in the first step is lower than a second increase rate of the first voltage in the second condition.

13. The semiconductor memory device according to claim 12, wherein a third increase rate of the first voltage in the second step is higher than the second increase rate.

14. The semiconductor memory device according to claim 6, wherein a first period in which the first condition is executed, a second period in which the second condition is executed, and a third period in which the third condition is executed are equal in length.

15. The semiconductor memory device according to claim 6, wherein:
the third condition includes a third step executed first and a fourth step executed subsequent to the third step; and
a fourth increase rate of the first voltage in the third step is higher than a second increase rate of the first voltage in the second condition.

16. The semiconductor memory device according to claim 15, wherein a fifth increase rate of the first voltage in the fourth step is lower than the second increase rate.

17. The semiconductor memory device according to claim 1, wherein the control circuit is further configured to apply a second voltage lower than the first voltage to the first word line in the program verify operation of the first memory cell.

18. The semiconductor memory device according to claim 1, wherein the second memory cell which is applied the first voltage is set to an ON state.

19. The semiconductor memory device according to claim 1, wherein the control circuit is further configured to set the first select transistor in an ON state in the program verify operation.
